(19) United States
(12) Patent Application Publication
(10) Pub. No.: US 2009/0134452 A1
(43) Pub. Date: May 28, 2009

(54) NON-VOLATILE MEMORY

(75) Inventors: Ching-Sung Yang, Hsinchu City (TW); Wei-Zhe Wong, Tainan City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: POWERCHIP SEMICONDUCTOR CORP., Hsinchu (TW)

(21) Appl. No.: 12/341,984

(22) Filed: Dec. 22, 2008

Related U.S. Application Data
(62) Division of application No. 11/307,871, filed on Feb. 26, 2006.

(30) Foreign Application Priority Data
Aug. 19, 2005 (TW) 94128349

(51) Int. Cl. H01L 29/792

(52) U.S. Cl. 257/325; 257/E29.309

(57) ABSTRACT

A non-volatile memory includes a substrate, a memory unit array, (N+1) bit lines, M word lines, M first control gate lines, and M second control gate lines. The memory unit array includes N memory unit columns, and each memory unit column includes M memory units. The (N+1) bit lines are disposed on the substrate and arranged in parallel in the column direction, and the (N+1) bit lines are corresponding to the N memory unit columns. The M word lines are disposed on the substrate and arranged in parallel in the row direction. The M first control gate lines are arranged on the substrate in parallel in the row direction and respectively connected to the first memory cell in the same row. The M second control gate lines are arranged on the substrate in parallel in the row direction and respectively connected to the second memory cell in the same row.

### CROSS-REFERENCE TO RELATED APPLICATION

This application is a divisional of an application Ser. No. 11/307,871, filed on Feb. 26, 2006, now pending, which claims the priority benefit of Taiwan application serial no. 94128349, filed on Aug. 19, 2005. The entirety of each of the above-mentioned patent applications is hereby incorporated by reference herein and made a part of this specification.

### BACKGROUND OF THE INVENTION

1. Field of Invention

The present invention relates to a semiconductor device. More particularly, the present invention relates to a non-volatile memory, manufacturing method and operating method thereof.

2. Description of Related Art

Among the various types of non-volatile memory products, electrically erasable programmable read only memory (EEPROM) is a memory device that has been widely used inside personal computer systems and electron equipment. In an EEPROM, data can be stored, read out or erased numerous times and any stored data can be retained even after power is cut off.

Typically, a floating gate and control gate of an EEPROM cell are fabricated using doped polysilicon. On the other hand, because doped polysilicon is used to fabricate the floating gates, any defects in the tunneling oxide layer under the floating gate can easily produce a leakage current and affect the reliability in the device.

Therefore, in the conventional technology, a charge trapping layer may be adopted to substitute the polysilicon floating gate, and the material of the charge trapping layer is, for example, silicon nitride. There is usually a silicon oxide layer above and under the silicon nitride charge trapping layer to form an oxide-nitride-oxide (ONO) composite layer. The device is usually called silicon/oxide-nitride-oxide/silicon (SONOS) device. As silicon nitride has an electron-trapping characteristic, the electrons injected into the charge trapping layer may concentrate in a partial area of the charge trapping layer. Therefore, it has little sensitivity to the defeat of the tunneling oxide layer, and the leakage current in device is more unlikely to occur.

Along with the requirement of high speed operation and low cost in the non-volatile memory, a virtually grounded memory structure suitable for SONOS device is introduced in the market. The virtually grounded memory structure can increase the density of the memory array, and is compatible with the current manufacturing process of the semiconductor devices.

However, the virtually grounded memory structure still has many disadvantages. One of the disadvantages is the program interference between each other. That is, when performing a program operation for a selected memory cell, a non-selected memory cell adjacent to the selected memory cell would also be programmed. The second disadvantage is that a current may leak into the adjacent memory cell, causing reduced reading current when reading. The third disadvantage is that the virtually grounded memory structure adopts embedded source/drain diffusion region as bit line (embedded bit line). As the embedded source/drain diffusion region has high resistance, the voltage may decrease along the embedded source/drain diffusion region, resulting in programming efficiency change and low read current. The above conditions may affect the read, erasing, and write operation for each memory cell, and accordingly, the speed of reading the memory cell is reduced.

### SUMMARY OF THE INVENTION

Accordingly, one aspect of the present invention is directed to provide a non-volatile memory, a manufacturing method and operating method thereof, which can improve the memory cell integrity and device efficiency.

Another aspect of the present invention is to provide a non-volatile memory, a manufacturing method and operating method thereof, in which programming operation and reading operation can be stably performed for memory cells, and the programming speed and memory efficiency can be improved.

The present invention provides a non-volatile memory, including a first memory unit, a first bit line and a second bit line. The first memory unit includes a first doped region, a second doped region, a first memory cell, a first select gate structure, and a second memory cell. The first doped region and the second doped region are formed in the substrate. The first memory cell, the first select gate structure, and the second memory cell are formed between the first doped region and the second doped region on the substrate. The first memory cell is adjacent to the first doped region and the second memory cell is adjacent to the second doped region. The first select gate structure is sandwiched between the first memory cell and the second memory cell. The first bit line and the second bit line are formed on the substrate in parallel, wherein, the first doped region is electrically connected to the first bit line, and the second doped region is electrically connected to the second bit line.

In the non-volatile memory, the first memory cell includes a first gate and a first composite layer. The second memory cell includes a second gate and a second composite layer. The first composite layer is disposed under the first gate, and includes a first bottom dielectric layer, a first charge storage layer and a first top dielectric layer. The second composite layer is disposed under the second gate, and includes a second bottom dielectric layer, a second charge storage layer and a second top dielectric layer. The material of the first charge storage layer and the second charge storage layer includes silicon nitride and doped polysilicon. The material of the first bottom dielectric layer and the second bottom dielectric layer includes silicon oxide. The material of the first top dielectric layer and the second top dielectric layer includes silicon oxide or the composite layer of oxide-nitride-oxide.

In the non-volatile memory, a pair of first insulation spacers are disposed on the sidewall of the first memory cell; a pair of second insulation spacers are disposed on the sidewall of the second memory cell. The material of the first insulation spacer and the second insulation spacer includes silicon oxide or silicon nitride.

In the non-volatile memory, the select gate structure includes a select gate and a select gate dielectric layer. The select gate dielectric layer is disposed under the select gate.

In the non-volatile memory, the first doped region is electrically connected to the first bit line via a first conductive plug, and the second doped region is electrically connected to the second bit line via a second conductive plug.

The non-volatile memory further includes a second memory unit and a third bit line. The second memory unit includes a third doped region, a fourth doped region, a third memory cell, a second select gate structure, and a fourth memory cell. The third doped region and the fourth doped region are formed in the substrate. The third memory cell, the second select gate structure, and the fourth memory cell are formed between the third doped region and the fourth doped region on the substrate. The third memory cell is adjacent to the third doped region and the fourth memory cell is adjacent to the fourth doped region. The second select gate structure is formed between the third memory cell and the fourth memory cell. The third bit line is formed on the substrate, wherein, the third doped region is electrically connected to the second bit line, and the fourth doped region is electrically connected to the third bit line.

In the non-volatile memory of the present invention, as there is no space among the first memory cell, the select gate structure and the second memory cell, the integrity of the memory cell array can be improved. And, both of the first memory cell and the second memory cell can store charges, so that the double bit data can be stored in a single memory unit. Accordingly, the storage capacity can be enhanced. Moreover, the material of the select gate structure dielectric layer of the select gate structure is silicon oxide, so that the switch of the select gate structure can be controlled more easily. In addition, the non-volatile memory of the present invention adopts the conductive wire as the bit line, but not the doped region (i.e., the so-called embedded bit line) as the bit line, so that the known disadvantages, such as the low programming efficiency and the low reading current resulting from the high resistance, can be avoided.

The present invention provides a non-volatile memory, including: a substrate, a memory unit array, (N+1) bit lines, M word lines, M first control gate lines and M second control gate lines. The memory unit array includes N memory unit columns, and each memory unit column includes M memory units (both N and M are positive integers). Each memory unit includes two doped regions, a first memory cell, a select gate structure, and a second memory cell. The two doped regions are disposed in the substrate. The first memory cell, the select gate structure, and the second memory cell are formed between the two doped regions on the substrate. The select gate structure is sandwiched between the first memory cell and the second memory cell. Among the memory units in the same column, every adjacent memory units share a common doped region, and the memory units are connected in series. The (N+1) bit lines are disposed on the substrate and arranged in parallel in the column direction, and the (N+1) bit lines are corresponding to the N memory unit columns, wherein, each of the N memory unit columns is disposed between every two adjacent bit lines, and the doped regions included in the memory unit column are connected to the corresponding two bit lines alternatively. The M word lines are disposed on the substrate, respectively, and the word lines are arranged in parallel in the row direction and respectively connected to the select gate structure in the same row. The M first control gate lines are arranged on the substrate in parallel in the row direction and respectively connected to the first memory cell in the same row. The M second control gate lines are arranged on the substrate in parallel in the row direction and respectively connected to the second memory cell in the same row.

In the non-volatile memory, the first memory cell includes a first gate and a first composite layer. The second memory cell includes a second gate and a second composite layer. The first composite layer is disposed under the first gate, and includes a first bottom dielectric layer, a first charge storage layer and a first top dielectric layer. The second composite layer is disposed under the second gate, and includes a second bottom dielectric layer, a second charge storage layer and a second top dielectric layer. The material of the first charge storage layer and the second charge storage layer includes silicon nitride or doped polysilicon. The material of the first bottom dielectric layer and the second bottom dielectric layer includes silicon oxide. The material of the first top dielectric layer and the second top dielectric layer includes silicon oxide or oxide-nitride-oxide composite layer.

In the non-volatile memory, a pair of first insulation spacers are disposed on the sidewall of the first memory cell; a pair of second insulation spacers are disposed on the sidewall of the second memory cell. The material of the first insulation spacer and the second insulation spacer includes silicon oxide or silicon nitride.

In the non-volatile memory, the select gate structure includes a select gate and a select gate dielectric layer. The select gate dielectric layer is disposed under the select gate.

The non-volatile memory further includes a first control line and a second control line, which are arranged on the substrate in parallel in the column direction, and respectively connected to the M first control gate lines and the M second control gate lines.

The non-volatile memory further includes four gate lines and 2(N+1) transistors. Each two of the four gate lines are disposed on two sides of the memory unit array, respectively, and the gate lines are arranged in parallel in the row direction, crossing with the (N+1) bit lines. The 2(N+1) transistors are disposed at the two ends of these (N+1) bit lines. The two bit lines are connected to the gate lines via the transistors, respectively, and each one of four adjacent bit lines have their transistors connect to at least one different gate lines from the other bit lines.

The present invention provides a non-volatile memory, including: a substrate, a first array, and a second array. Each of the first array and the second array includes 4N memory unit columns, (4N+1) bit lines, M word lines, M first control gate lines and M second control gate lines. For the 4N memory unit columns, each memory unit column includes M memory units (both N and M are positive integers). (4N+1) bit lines are arranged on the substrate in parallel in the column direction. Each memory unit includes two doped regions, a first memory cell, a select gate structure, and a second memory cell. The two doped regions are formed in the substrate. The first memory cell, the select gate structure, and the second memory cell are disposed in series on the substrate between the two doped regions. The select gate structure is sandwiched between the first memory cell and the second memory cell. Among the memory units in the same column, the two adjacent memory units share a doped region, and the memory units are connected in series in opposite direction. Each one of the 4N memory unit columns is disposed between every two adjacent bit lines, and the doped regions of the memory unit column are connected to the corresponding two bit lines alternatively. The M word lines are disposed on the substrate, respectively, and the word lines are arranged in parallel in the row direction and respectively connected to the select gate structure in the same row. The M first control gate lines are arranged on the substrate in parallel in the row direction and respectively connected to the first memory cell in the same row. The M second control gate lines are arranged on the substrate in parallel in the row direction and respectively connected to the second memory cell in the same row.

In the non-volatile memory, the first memory cell includes a first gate and a first composite layer. The second memory cell includes a second gate and a second composite layer. The first composite layer is disposed under the first gate, and includes a first bottom dielectric layer, a first charge storage layer and a first top dielectric layer. The second composite layer is disposed under the second gate, and includes a second bottom dielectric layer, a second charge storage layer and a second top dielectric layer. The material of the first charge storage layer and the second charge storage layer includes silicon nitride or doped polysilicon.

In the non-volatile memory of the present invention, as there is no space among the first memory cell, the select gate structure and the second memory cell, the integrity of the memory cell array is improved. And, both of the first memory cell and the second memory cell can store charges, so that a double bit data can be stored in a single memory unit. Accordingly, the storage capacity can be enhanced. Moreover, the material of the select gate structure dielectric layer of the select gate structure is silicon oxide, so that the switch of the select gate structure can be controlled more easily. In addition, the non-volatile memory of the present invention adopts conductive wire as the bit line, but not the doped region (i.e., the so-called embedded bit line) as the bit line, so that the disadvantages, such as low programming efficiency and the low reading current resulting from the known high resistance, can be avoided.

The present invention provides an operating method of non-volatile memory, suitable for a memory unit array. The memory unit array includes: a plurality of memory units, and each of the memory units includes: a first doped region, a second doped region, a first memory cell, a select gate structure and a second memory cell, disposed on the substrate between the first doped region and the second doped region. The first memory cell is adjacent to the first doped region. The second memory cell is adjacent to the second doped region. The select gate structure is disposed between the first memory cell and the second memory cell. The first doped region is connected to the first bit line. The second doped region is connected to the second bit line. The word line is connected to the select gate structure. The first control gate line is connected to the first memory cell. The second control gate line is connected to the second memory cell. The method is as follows. When programming the first memory cell of a selected memory unit, a first voltage is applied on the first bit line connected to the selected memory unit; a second voltage is applied on the first and second control gate line, respectively; a third voltage is applied on the word line connected to the selected memory unit; a fourth voltage is applied on the second selected bit line connected to the selected memory unit; the first memory cell of the selected memory unit is programmed by source-side injection (SSI) effect, wherein, the voltage difference between the second voltage and the first voltage is greater than the threshold voltage of the first memory cell and the third voltage is equal to the threshold voltage of the select gate structure.

In the operating method of non-volatile memory, the first voltage is about 4.5 voltage; the second voltage is about 7 voltage; the third voltage is about 1.5 voltage; and the fourth voltage is about 0 voltage.

In the operating method of non-volatile memory, when erasing the memory unit, a fifth voltage is applied on the first and the second control gate lines, respectively; a sixth voltage is applied on the substrate; and to the first bit line and the second bit line are floating; the memory units are erased by FN tunneling effect, wherein the voltage difference between the sixth voltage and the fifth voltage is sufficient to induce the FN tunneling effect.

In the operating method of non-volatile memory, the fifth voltage is about 0 voltage, and the sixth voltage is about 12 voltage.

In the operating method of non-volatile memory, the fifth voltage is about −6 voltage; and the sixth voltage is about 6 voltage.

In the operating method of non-volatile memory, when reading the selected memory unit, a seventh voltage is applied on the first control gate line connected to the selected memory unit; an eighth voltage is applied on the second control gate line connected to the selected memory unit; a ninth voltage is applied on the selected word line; a tenth voltage is applied on the first bit line; and an eleventh voltage is applied on the second bit line to read the first memory cell of the selected memory unit. Wherein, the ninth voltage and the eighth voltage are respectively greater than or equal to the threshold voltages of the word line or the control gate line; the tenth voltage is greater than the eleventh voltage, and the seventh voltage is 0 voltage.

In the operating method of non-volatile memory, the eighth voltage is about 3.3 voltage; the ninth voltage is about 3.3 voltage; the tenth voltage is about 1.5 voltage; and the eleventh voltage is about 0 voltage.

In the operating method of the non-volatile memory, the program operation for the memory cell is performed by source-side injection (SSI) effect, and the erasing operation of the memory cell is performed by FN tunneling effect. Accordingly, the electron injection efficiency is high, the memory cell current in operation can be reduced, and the operation speed can be improved simultaneously. Therefore, the current consumption is small, and the power waste of the whole chip can be reduced effectively.

The present invention provides a manufacturing method of a non-volatile memory, described as follows. First, a substrate is provided; and two stacked gate structures are formed on the substrate. There is a gap between the two stacked gate structures, and the two stacked gate structures at least include a charge storage layer, respectively. A select gate structure is formed in the gap between the two stacked gate structures. The select gate structure is connected to the two stacked gate structures in series without space. Thereafter, a first doped region and a second doped region are formed on the substrate outside of the two stacked gate structures, respectively, and two bit lines are formed on the substrate, and the two bit lines are connected to the first doped region and the second doped region, respectively.

In the manufacturing method of a non-volatile memory, the method of forming the two stacked gate structures on the substrate is as follows. After the tunneling dielectric layer, the charge storage layer, the inter-gate dielectric layer, the first conductive layer and the cap layer are formed on the substrate in sequence, the cap layer, the first conductive layer, the inter-gate dielectric layer, the charge storage layer and the tunneling dielectric layer are patterned.

In the manufacturing method of a non-volatile memory, the material of the charge storage layer includes silicon nitride. The material of the tunneling dielectric layer and the inter-gate dielectric layer includes silicon oxide. The material of the charge storage layer also includes doped polysilicon. The material of the tunneling dielectric layer includes silicon oxide. The material of the inter-gate dielectric layer includes a composite layer of oxide-nitride-oxide.

The manufacturing method of a non-volatile memory further includes: after the step of forming the two stacked gate structures on the substrate, forming an insulation spacer on the side walls of the two stacked gate structures.

In the manufacturing method of a non-volatile memory, the step of forming the select gate structure in the gap includes: forming a gate dielectric layer on the substrate in advance; then, forming a second conductive layer on the substrate to fill the gap.

The manufacturing method of a non-volatile memory further includes: forming two conductive plugs on the substrate, wherein the two conductive plugs connect the two bit lines and the first doped region with the second doped region, respectively.

In the manufacturing method of the non-volatile memory of the present invention, as the select gate dielectric layer and the select gate are formed between the two stacked gate structures, another transistor can be formed between the two stacked gate structures and the photolithography etching process is not required. Therefore, the manufacturing process is simple, and the cost can be reduced. Moreover, the non-volatile memory of the present invention adopts the conductive wire as the bit line, but not the doped region (i.e., the so-called embedded bit line) as the bit line, so that the known disadvantages, such as the low programming efficiency and the low reading current, can be avoided.

In order to the make the aforementioned and other features and advantages of the present invention comprehensible, embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a cross-sectional diagram of a non-volatile memory unit according to one embodiment of the present invention.

FIG. 1B is a cross-sectional diagram of a non-volatile memory unit according to another embodiment of the present invention.

FIG. 2A is a schematic diagram of a circuit of the non-volatile memory array according to one embodiment of the present invention.

FIG. 2B is a schematic diagram of a circuit of the non-volatile memory array according to another embodiment of the present invention.

FIG. 3A is a schematic diagram of a programmable operation method of the non-volatile memory unit according to one embodiment of the present invention.

FIG. 3B is a schematic diagram of a programmable operation method of the non-volatile memory unit according to one embodiment of the present invention.

FIG. 3C is a schematic diagram of an erasing operation of the non-volatile memory unit according to one embodiment of the present invention.

FIG. 3D is a schematic diagram of another erasing operation of the non-volatile memory unit according to one embodiment of the present invention.

FIG. 3E is a schematic diagram of a reading operation of the non-volatile memory unit according to one embodiment of the present invention.

FIG. 3F is a schematic diagram of a reading operation of the non-volatile memory unit according to one embodiment of the present invention.

FIG. 4A to FIG. 4F are flow charts of the manufacturing process of the non-volatile memory according to one embodiment of the present invention.

### DESCRIPTION OF EMBODIMENTS

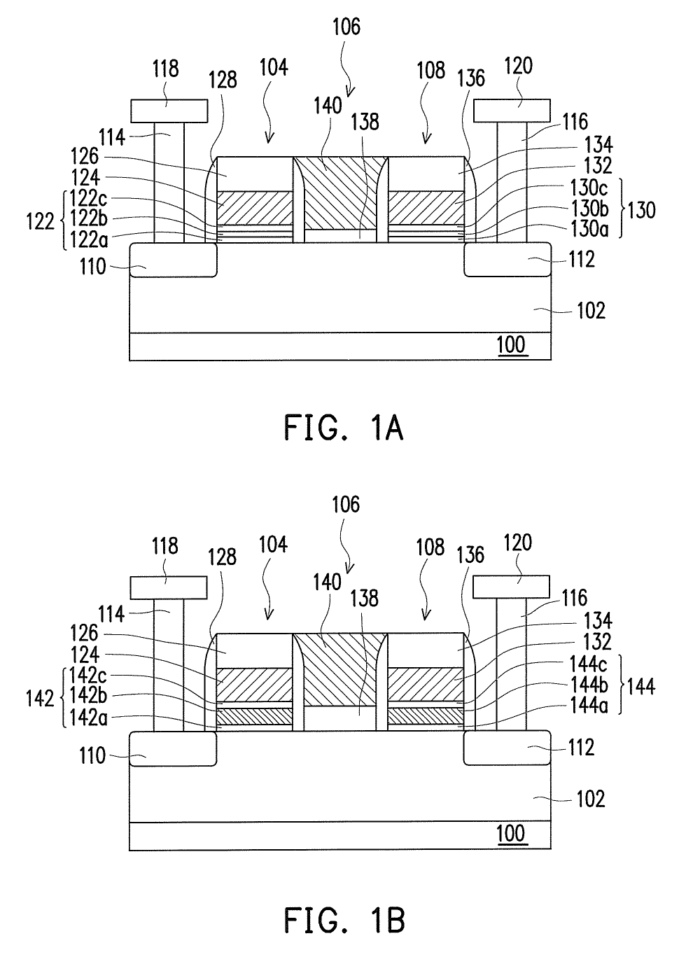

FIG. 1A is a cross-sectional diagram of a non-volatile memory unit according to one embodiment of the present invention.

Referring to FIG. 1A, the non-volatile memory unit of the present invention includes: a substrate 100, a well region 102, a memory cell 104, a select gate structure 106, a memory cell 108, a doped region 110, a doped region 112, a conductive plug 114, a conductive plug 116, a conductive wire 118 (bit line), and a conductive wire 120 (bit line).

The substrate 100 is, for example, silicon substrate. The substrate 100 can be a P-type substrate or an N-type substrate. The well region 102 is, for example, disposed in the substrate 100.

The doped region 110 and the doped region 112 are, for example, disposed in the substrate 100. The memory cell 104, the select gate structure 106 and the memory cell 108 are, for example, disposed on the substrate 100 between the doped region 110 and the doped region 112. The memory cell 104 is adjacent to the doped region 110. The memory cell 108 is adjacent to the doped region 112. The memory cell 104, the select gate structure 106 and the memory cell 108 are, for example, connected to each other in series without space. The select gate structure 106 is sandwiched between memory cell 104 and memory cell 108.

The memory cell 104 is disposed on the substrate 100, including: for example, a composite layer 122, a gate 124, and a cap layer 126. The gate 124 is disposed on the substrate 100. The composite layer 122 is disposed between the gate 124 and the substrate 100. The composite layer 122 is a bottom dielectric layer 122a, a charge storage layer 122b, and a top dielectric layer 122c sequentially from the substrate 100. The cap layer 126 is disposed on the gate 124. The material of the bottom dielectric layer 122a is, for example, silicon oxide; the material of the charge storage layer 122b is, for example, silicon nitride; and the material of the top dielectric layer 122c is, for example, silicon oxide. The material of the gate 124 is, for example, doped polysilicon. The material of the cap layer 126 is, for example, silicon oxide.

Moreover, an insulation spacer 128 can also be disposed on the side walls of the gate 124 and the composite layer 122. The material of the insulation spacer 128 includes an insulation material, such as silicon nitride or silicon oxide.

The memory cell 108 is disposed on the substrate 100, including: for example, a composite layer 130, a gate 132, and a cap layer 134. The gate 132 is disposed on the substrate 100. The composite layer 130 is disposed between the gate 132 and the substrate 100. The composite layer 130 is a bottom dielectric layer 130a, a charge storage layer 130b, and a top dielectric layer 130c sequentially from the substrate 100. The cap layer 134 is disposed on the gate 132. The material of the bottom dielectric layer 130a is, for example, silicon oxide; the material of the charge storage layer 130b is, for example, silicon nitride; and the material of the top dielectric layer 130c is, for example, silicon oxide. The material of the gate 132 is, for example, doped polysilicon. The material of the cap layer 134 is, for example, silicon oxide.

Moreover, an insulation spacer 136 can also be disposed on the side walls of the gate 132 and the composite layer 130. The material of the insulation spacer 136 includes an insulation material, such as silicon nitride or silicon oxide.

The select gate structure 106 is, for example, disposed in the gap between the memory cell 104 and the memory cell 108. The select gate structure 106 is, for example, composed of a select gate 140 and a select gate dielectric layer 138. The material of the select gate 140 is, for example, doped polysilicon. The material of the select gate dielectric layer is, for example, silicon oxide.

The conductive wire 118 (bit line) and the conductive wire 120 (bit line) are, for example, disposed on the substrate 100 in parallel. The doped region 110, for example, is electrically connected to the conductive wire 118 (bit line) through the conductive plug 114. The doped region 112 is electrically connected to the conductive wire 120 (bit line) through a conductive plug 116.

And, in another embodiment of the present invention, as shown in FIG. 1B, the composite layer 142 of the memory cell 104 is, for example, composed of a tunneling dielectric layer 142a (a bottom dielectric layer), a floating gate 142b (a charge storage layer) and an inter-gate dielectric layer 142c (a top dielectric layer). The material of the tunneling dielectric layer 142a (the bottom dielectric layer) is, for example, silicon oxide. The material of the floating gate 142b (the charge storage layer) is, for example, doped polysilicon. The material of the inter-gate dielectric layer 142c (the top dielectric layer) is, for example, a composite layer of oxide-nitride-oxide. Also, the composite layer 144 of the memory cell 108 is, for example, composed of a tunneling dielectric layer 144a (a bottom dielectric layer), a floating gate 144b (a charge storage layer) and an inter-gate dielectric layer 144c (a top dielectric layer). The material of the tunneling dielectric layer 144a (bottom dielectric layer) is, for example, silicon oxide. The material of the floating gate 144b (charge storage layer) is, for example, doped polysilicon. The material of the inter-gate dielectric layer 144c (top dielectric layer) is, for example, a composite layer of oxide-nitride-oxide.

In the non-volatile memory unit, there is no space among the memory cell 104, the select gate structure 106 and the memory cell 108, so that the integrity of the memory cell array is improved. And, both of the memory cell 104 and the memory cell 106 can store charges, so that a double bit data can be stored in single memory unit. Accordingly, the storage capacity is enhanced. Moreover, the material of the select gate structure dielectric layer 138 of the select gate structure 106 is silicon oxide, so that the switch of the select gate structure can be controlled more easily. In addition, the non-volatile memory unit of the present invention adopts the conductive wire as the bit line, but not the doped region (i.e., the so-called embedded bit line) as the bit line, so that the known disadvantages, such as the low programming efficiency and the low reading current resulting from the high resistance, can be avoided.

Next, the array structure of the non-volatile memory according to one embodiment of the present invention is described.

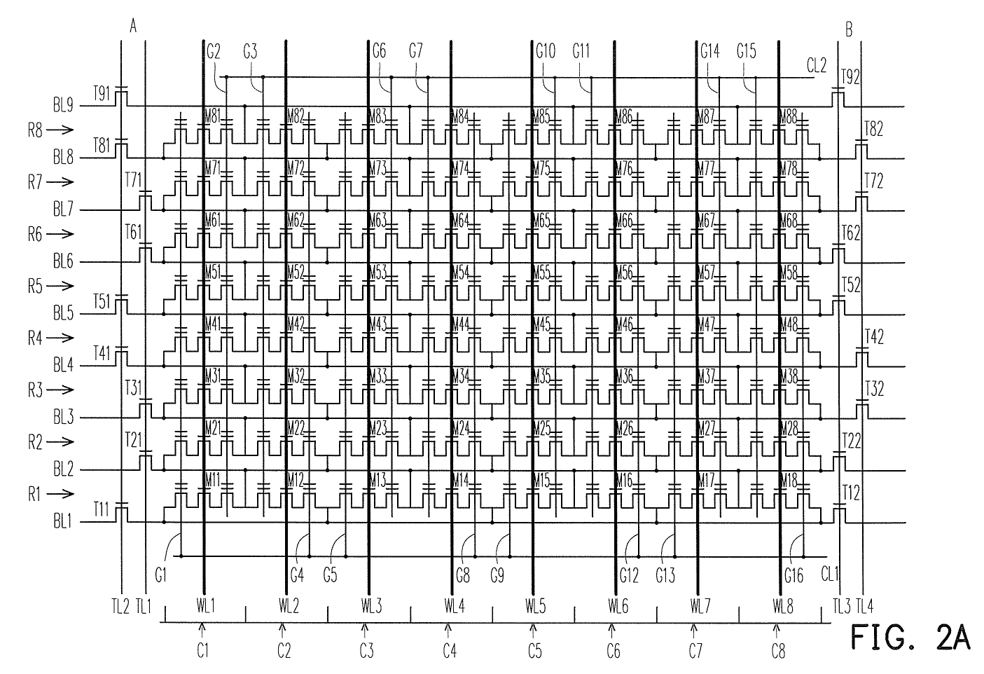

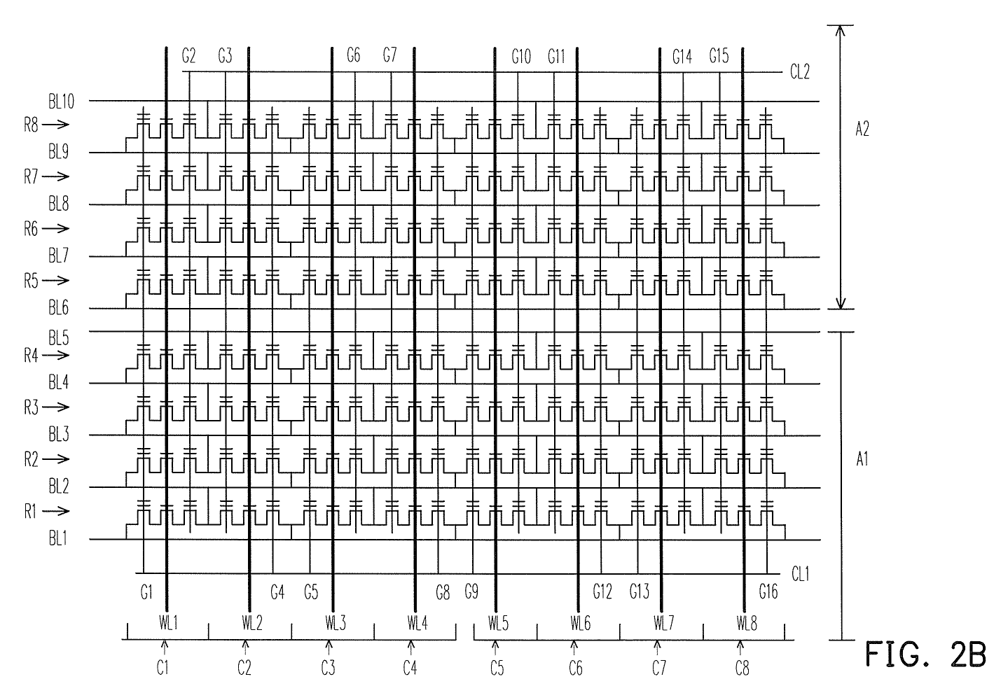

FIG. 2A is a schematic diagram of a circuit of the non-volatile memory array according to one embodiment of the present invention.

Referring to FIG. 2A, in the non-volatile memory of the present invention, M memory units (M is a positive integer. In the embodiment, M is 8) are connected to each other in series to form a memory unit column R1-R8 in the column direction; N memory units (N is a positive integer. In the embodiment, N is 8) are connected to each other in series to form a memory unit row C1-C8 in the row direction.

The non-volatile memory, for example, includes M×N (64) memory units M11-M88, M (8) word lines WL1-WL8, (N+1) (9) bit lines BL1-BL9, 2M (16) control gate lines G1-G16, a plurality of (2) control lines CL1-CL2, 2(N+1) (18) transistors T11-T92, and a plurality of (4) gate lines TL1-TL4.

Each of the memory units M11-M88, for example, has the structure as shown in FIG. 1A or FIG. 1B, including two doped regions, two memory cells and a select gate structure. In the following description, for each memory unit in FIG. 2A, the doped region and the memory cell close to the reference number A (left side) are called A side doped region and A side memory cell; the doped region and the memory cell close to the reference number B (right side) are called B side doped region and B side memory cell.

In the column direction, the memory unit columns R1-R8 are composed of 8 memory units, respectively. In each of the memory unit columns R1-R8, the two adjacent memory units share one doped region. For example, the memory unit column R1 is formed by connecting the memory unit M11, memory unit M12, . . . , memory unit M18 in series, wherein, the memory unit M11 and the memory unit M12 share one doped region; the memory unit M12 and the memory unit M13 share one doped region; . . . ; the memory unit M17 and the memory unit M18 share one doped region. The memory unit column R2 is formed, for example, by connecting the memory unit M21, memory unit M22, . . . , and memory unit M28 in series, wherein, the memory unit M21 and the memory unit M22 share one doped region; the memory unit M22 and the memory unit M23 share one doped region; . . . ; the memory unit M27 and the memory unit M28 share one doped region. The rest may be deduced by analogy: the memory unit column R8 is formed by connecting the memory unit M81, memory unit M82, . . . , and memory unit M88 in series, wherein, the memory unit M81 and the memory unit M82 share one doped region; the memory unit M82 and the memory unit M83 share one doped region; . . . ; the memory unit M87 and the memory unit M88 share one doped region.

In the row direction, the memory unit rows C1-C8 are formed by arranging 8 memory units, respectively. For example, the memory unit row C1 is formed by arranging the memory unit M11, memory unit M21, . . . , and memory unit M81. The memory unit row C2 is formed by arranging the memory unit M12, memory unit M22, . . . , and memory unit M82. The rest may be deduced by analogy: the memory unit row C8 is formed by arranging the memory unit M18, memory unit M28, . . . , and memory unit M88.

(N+1) bit lines BL1-BL9 are, for example, disposed on the substrate, respectively. These bit lines BL1-BL9 are arranged in parallel in the column direction. These (N+1) bit lines are corresponding to N memory unit columns, wherein, one memory unit column is disposed between two adjacent bit lines, and the doped regions included in the memory unit column are respectively connected to the corresponding two adjacent bit lines in an interlacing manner. For example, from A side to B side in the memory cell column R1 of the first column, the 1st, 3rd, 5th, 7th, 9th doped regions are electrically connected to the first bit line BL1, and the 2nd, 4th, 6th, 8th doped regions are electrically connected to the second bit line BL2. In the memory cell column R2 of the second column, the 1st, 3rd, 5th, 7th, 9th doped regions are electrically connected to the second bit line BL2, and the 2nd, 4th, 6th, 8th doped regions are electrically connected to the third bit line BL3. The rest may be deduced by analogy: in the memory cell column R8 of the eighth column, the 1st, 3rd, 5th, 7th, 9th doped regions are electrically connected to the eighth bit line BL8, and the 2nd, 4th, 6th, 8th doped regions are electrically connected to the ninth bit line BL9.

M word lines WL1-WL8 are, for example, disposed on the substrate, respectively. These word lines WL1-WL8 are arranged along the row direction in parallel, and connected to the gate of the select gate structure in the same row. For example, the word line WL1 is connected to the gate of the select gate structure of these memory units M1-M81 in the memory cell row C1. The word line WL2 is connected to the gate of the select gate structure of these memory units M12-M82 in the memory cell row C2. The rest may be deduced by analogy: the word line WL8 is connected to the gate of the select gate structure of these memory units M18-M88 in the memory cell row C8.

2M control gates G1-G8 are disposed on the substrate, respectively. These control gate lines G1-G16 are arranged along the row direction in parallel, and connected to the gate of the memory cell of the select gate structure in the same row. These 2M control gate lines are divided into two: M first control gate lines and M second control gate lines. In each column of memory units, each memory unit includes a first memory cell and a second memory cell, and each memory unit is connected in series in the opposite direction. The aforementioned M first control gate lines can be connected to the gates of the first memory cells in the same row. And, M second control gate lines can be connected to the gates of the second memory cells in the same row. In the embodiment, the control gate lines G1, G4, G5, G8, G9, G12, G13, G16 act as the first control gate lines. The control gate lines G2, G3, G6, G7, G10, G11, G14 and G15 act as the second control gate lines.

For example, the first control gate line G1 is connected to the gates of the first memory cells of the memory unit M11, memory unit M21, . . . , and memory unit 81. The second control gate line G2 is connected to the gates of the second memory cells of the memory unit M11, memory unit M21, . . . , and memory unit 81. Another second control gate line G3 is connected to the gates of the second memory cells of the memory unit M12, memory unit M22, . . . , and memory unit 82. Another first control gate line G4 is connected to the gates of the first memory cells of the memory unit M12, memory unit M22, . . . , and memory unit 82. The rest may be deduced by analogy.

A plurality of control lines (two in the embodiment) CL1 and CL2 are arranged in the column direction in parallel, and the control gate line G1-G16 is connected to the two control lines CL1 and CL2, respectively. Wherein, M first control gate lines are connected to one control line CL1, while other M control gate lines are connected to another control line CL2. For example, the first control gate lines G1, G4, G5, G8, G9, G12, G13 and G16 are connected to the control line CL1; while the second control gate lines G2, G3, G6, G7, G14 and G15 are connected to the control line CL2.

M (four in the embodiment) gate lines TL1-TL4 are arranged in the row direction in parallel, with every two forming a group, disposed in the two ends of the (N+1) bit lines BL1-BL9, respectively. Wherein, a transistor is disposed at the two ends of each bit line to be connected to the corresponding gate line. Every four bit lines are a unit for the (N+1) bit lines, and the transistors at the two ends of any two bit lines would not be connected to the same two gate lines. While, the transistors at the two ends of the most outside bit line are disposed repeatedly, and the configuration is the same as the configuration of the furthest bit line in the adjacent four bit lines. The bit lines are connected to the gate lines via transistors respectively and each one of four adjacent bit lines have their transistor connect to at least one different gate line from the other bit lines.

The non-volatile memory of the present invention adopts the conductive wires as the bit lines BL1-BL9, but not the doped region (i.e., the so-called embedded bit line) as the bit line, so that the known disadvantages, such as the low programming efficiency and the low reading current resulting from the high resistance, can be avoided.

In the entire array in the embodiment, except for the bit lines of the first column and the last column, all the bit lines are shared by the adjacent memory unit columns. For example, the memory unit array includes 8 memory unit columns and 9 bit lines, and a transistor is disposed on the two sides of each bit line. Of course, the non-volatile memory of the present invention can also be grouped by every four memory unit columns, as shown in FIG. 2B, wherein, every four memory unit columns and the next four memory unit columns do not share the bit lines.

For example, as shown in FIG. 2B, the memory unit columns R1-R4 are one group, forming an array A1; the memory unit columns R5-R8 are one group, forming an array A2. The array A1 includes the bit lines BL1-BL5, and the array A2 includes the bit lines BL6-BL10. That is, the arrays A1 and A2 do not share bit lines, but share the word lines and the control gate lines. Moreover, the arrays A1 and A2 are not limited to being composed of 4 memory unit columns, and can also be composed of 8, 16, 32 or 64 memory unit lines.

In addition, for the non-volatile memory of the present invention, the quantity of the memory units connected in series in one memory cell column depends on the actual requirement. For example, the same memory cell column can connect 16, 32 or 64 memory unit structures.

Next, the memory unit M21 is taken as an example to describe the operation method of the non-volatile memory of the present invention.

Referring to FIG. 2A and FIG. 2B, while performing the programming operation for the memory cell Q1 (A side memory cell) of the memory unit M21, a voltage Va, for example, about 7 voltage, is applied on the gate line TL1 to turn on the channel of the transistor T21 and the transistor T31; a voltage Vpb1, for example, about 4.5 voltage, is applied on the bit line BL2; a voltage Vpb2, for example, about 0 voltage, is applied on the bit line BL3; a voltage Vpc1, for example, about 7 voltage, is applied on the control line CL1 (the control gate line G1); a voltage Vpc2, for example, about 7 voltage, is applied on the control line CL2 (the control gate line G2); a voltage Vps, for example, about 1.5 voltage, is applied on the word line WL1 (the select gate structure) to inject electron to the charge storage layer of the memory cell Q1 using a source-side injection (SSI) effect. Accordingly, the memory cell Q1 is programmed. The voltage difference between the voltage Vpc1 (and the voltage Vpc2) and the voltage Vpb1 is greater than the threshold voltage of the memory cell Q1, and, the voltage Vps is equal to the threshold voltage of the select gate structure.

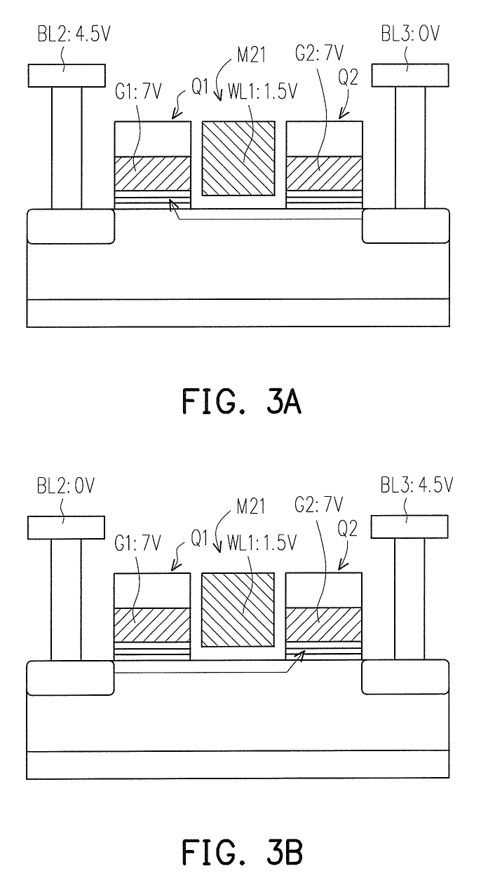

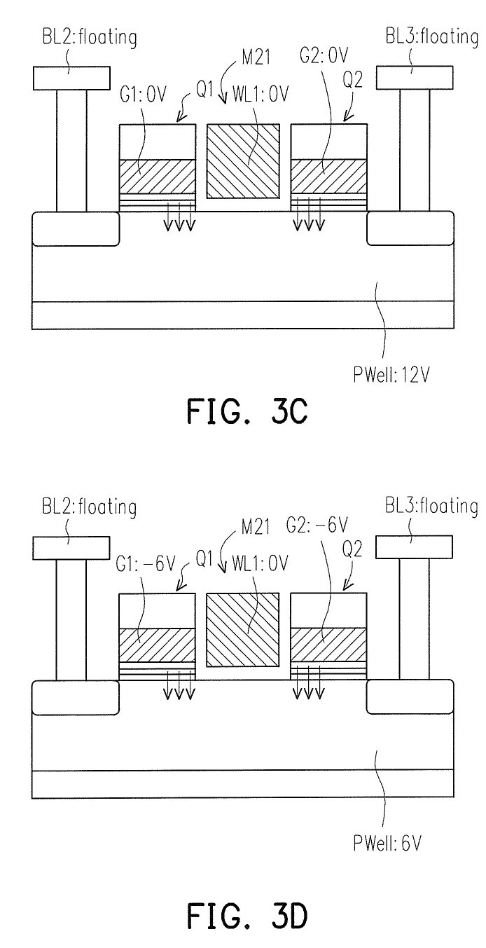

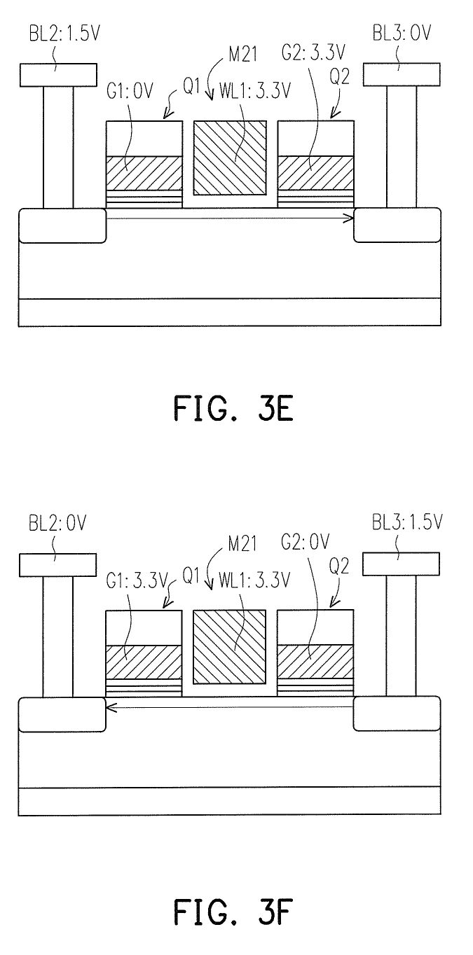

Referring to FIG. 2A and FIG. 3B simultaneously, while performing a programming operation for the memory cell Q2 (B side memory cell) of the memory unit M21, a voltage Va, for example, about 7 voltage, is applied on the gate line TL1 to turn on the channel of the transistor T21 and the transistor T31; a voltage Vpb1, for example, about 4.5 voltage, is applied on the bit line BL3; a voltage Vpb2, for example, about 0 voltage, is applied on the bit line BL2; a voltage Vpc1, for example, about 7 voltage, is applied on the control line CL1 (the control gate line G1); a voltage Vpc2, for example, about 7 voltage, is applied on the control line CL2 (the control gate line G2); a voltage Vps, for example, about 1.5 voltage, is applied on the word line WL1 (the select gate structure) to inject electron to the charge storage layer of the memory cell Q2 using source-side injection (SSI) effect. Accordingly, the memory cell Q2 is programmed. The voltage difference between the voltage Vpc1 (and the voltage Vpc2) and the voltage Vpb1 is greater than the threshold voltage of the memory cell Q2, and, the voltage Vps is equal to the threshold voltage of the select gate structure.

In the programming method, no voltages are applied to the gate lines TL2, TL3 and TL4. Accordingly, the transistors T1, T41, T22 and T42 are turned off, so that the leakage current can be avoided when the memory unit M21 is being programmed, and better programming efficiency can be obtained.

Referring to FIG. 2A and FIG. 3C, while performing the erasing operation, a voltage Vce, for example, about 0 voltage, is applied on the control line CL1 and the control line CL2 (the control gate lines G1-G16); a voltage Vwe, for example, about 12 voltage, is applied on the substrate (p type region), and the bit lines are floating. Accordingly, the entire memory cell array is erased by an F-N tunneling effect. The voltage difference between the voltage Vwe and the voltage Vce is sufficient to induce the FN tunneling effect.

Referring to FIG. 2 and FIG. 3D, while performing the erasing operation, a voltage Vce, for example, about −6 voltage, is applied on the control line CL1 and the control line CL2 (the control gate lines G1-G16); a voltage Vwe, for example, about 6 voltage, is applied on the substrate (p well region), and the bit lines are floating. Accordingly, the entire memory cell array is erased by an F-N tunneling effect. The voltage difference between the voltage Vwe and the voltage Vce is sufficient to induce the FN tunneling effect.

When performing an erasing operation using FN tunneling effect, an insulation well region is formed in the substrate. Then, a voltage is applied on the well region directly to prevent the entire chip from being charged so as to avoid wasting power.

Referring to FIG. 2 and FIG. 3E, while performing an reading operation for the memory cell Q1 (A side memory cell) of the memory unit M21, a voltage Va, for example about 3.3 voltage, is applied on the gate line TL1 to turn on the channel of the transistor T21 and the transistor T31; a voltage Vrb1, for example, about 1.5 voltage, is applied on the bit line BL2; a voltage Vpb2, for example, about 0 voltage, is applied on the bit line BL3; a voltage Vrc1, for example, about 0 voltage, is applied on the control line CL1 (the control gate line G1); a voltage Vrc2, for example, about 3.3 voltage, is applied on the control line CL2 (the control gate line G2); a voltage Vrs, for example, about 3.3 voltage, is applied on the word line WL1 (the select gate structure) to read the selected memory cell Q1. As the channel of the memory cell with minus overall charge is turned off and the current is small and the channel of the memory cell with slight positive overall charge is turn on and the current is large, the digital signal can be determined to be [1] or [0] according to the turn on/turn off status of the channel and/or the size of the channel current.

Referring to FIG. 2 and FIG. 3F, while performing an reading operation for the memory cell Q2 (B side memory cell) of the memory unit M21, a voltage Va, for example about 3.3 voltage, is applied on the gate line TL1 to turn on the channel of the transistor T21 and the transistor T31; a voltage Vrbl, for example, about 0 voltage, is applied on the bit line BL2; a voltage Vpb2, for example, about 1.5 voltage, is applied on the bit line BL3; a voltage Vrc1, for example, about 3.3 voltage, is applied on the control line CL1 (the control gate line G1); a voltage Vrc2, for example, about 0 voltage, is applied on the control line CL2 (the control gate line G2); a voltage Vrs, for example, about 3.3 voltage, is applied on the word line WL1 (the select gate structure) to read the selected memory cell Q2. As the channel of the memory cell with minus overall charge is turned off with a small current and the channel of the memory cell with slight positive overall charge is turned on with a large current, the digital signal can be determined to be [1] or [0] according to the turn on/turn off status of the channel and/or the size of the channel current.

In the reading method of the present invention, while reading one selected memory cell Q1 (or Q2) of the memory unit M21, the unselected memory cell Q2 (or Q1) acts as a pass transistor. While reading one selected memory cell Q1 (or Q2), the applied voltage needs to turn on the channel of the unselected memory cell Q2 (or Q1). Even if the selected memory cell Q2 (or Q1) has stored data, the determination of the selected memory cell Q1 (or Q2) would not be affected. Moreover, in the reading method, no voltage is applied on the gate lines TL2, TL3 and TL4, so the T11, T41, T12, T22, T32, T42 are all in turn off status. Therefore, leakage current can be avoided while reading the memory unit M21, and better reading efficiency is obtained.

In the operation method of the non-volatile memory of present invention, the programming operation for the memory cell is by source-side injection (SSI) effect, and the erasing operation for the memory cell is by FN tunneling effect. Accordingly, the electron injection efficiency is high, and the memory cell current in the operation can be reduced, at the same time, the operation speed is improved. Therefore, the current consumption is small, and the power waste of the entire chip can be reduced effectively.

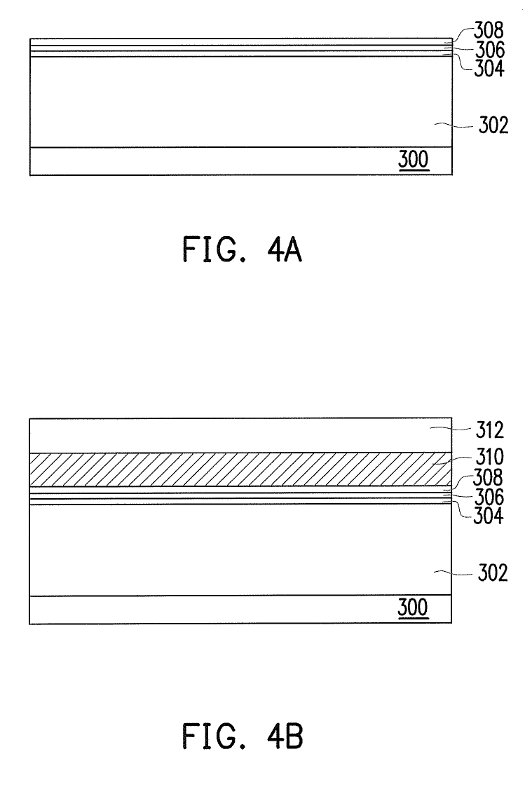

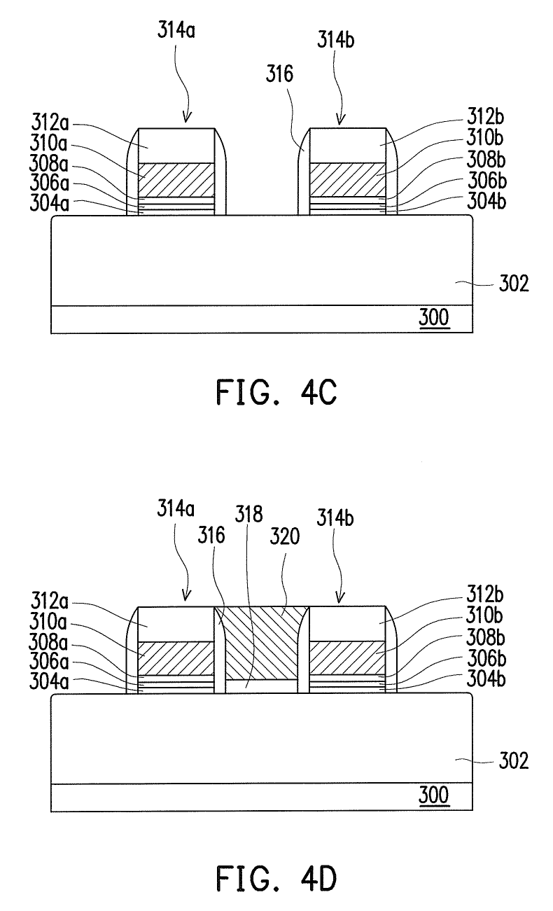

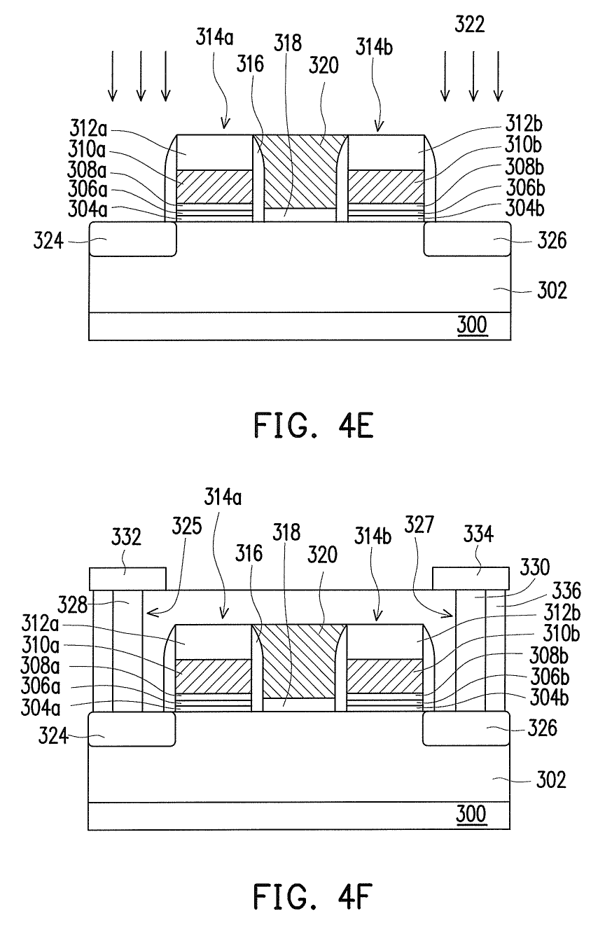

FIG. 4A to FIG. 4F are flow charts of the manufacturing process of the non-volatile memory according to one embodiment of the present invention.

First, referring to FIG. 4A, a substrate 300 is provided, and the substrate 300 is, for example, a silicon substrate. Next, a well region 302 is formed in the substrate 300. Then, a dielectric layer 304 is formed on the surface of the substrate 300 to act as the tunneling oxide layer, wherein the material of the dielectric layer 304 is, for example, silicon oxide and the forming method of the dielectric layer 304 is, for example, a thermal oxidation process.

Next, a charge storage layer 306 is formed in the dielectric layer 304, wherein the material of the charge storage layer 306 is, for example, charge trapping material (i.e., silicon nitride). The forming method of the charge storage layer 306 is, for example, a chemical vapor deposition (CVD) process. Of course, the material of the charge storage layer 306 can also be a conductive material (i.e., doped polysilicon). The forming method of the charge storage layer 306 is, for example, by performing an ion implanting process after an un-doped polysilicon is formed in a chemical vapor deposition (CVD) process; or, by adopting an in-situ ion implanting operation in a chemical vapor deposition (CVD) process. Thereafter, the electron storage layer 306 can be selectively patterned according to the actual requirement. For example, when the non-volatile memory unit as shown in FIG. 1B is to be made, the electron storage layer 306 needs first to be patterned as strips. Accordingly, the electron storage layer 306 can be divided into blocks in the subsequent process of forming the control gate. On the other hand, when the non-volatile memory unit as shown in FIG. 1A is to be made, the electron storage layer 306 needs not to be patterned in advance.

Next, referring to FIG. 4B, a dielectric layer 308, a conductive layer 310, and a cap layer 312 are formed in sequence on the substrate 300.

The material of the dielectric layer 308 is, for example, silicon oxide, and the forming method of the dielectric layer 308 is, for example, a chemical vapor deposition (CVD) process. Of course, the material of the dielectric layer 308 can also be a composite layer of oxide-nitride-oxide.

The material of the conductive layer 310 is, for example, doped polysilicon, and the forming method of the conductive layer 310 is, for example, by performing an ion-implanting process after a layer of non-doped polysilicon is formed, or, by forming an in-situ ion implanting operation in a chemical vapor deposition process.

The material of the cap layer 312 is, for example, silicon nitride or silicon oxide, and the forming method of the cap layer 312 is, for example, a chemical vapor deposition (CVD) process.

Referring to FIG. 4C, using the mask (not shown), the cap layer 312 and the conductive layer 310 are patterned to define the gate cap layer 312a (312b) and the conductive layer 310a (310b) serving as the control gate. The dielectric layer 308, the charge storage layer 306 and the tunneling dielectric layer 304 are defined using the same mask to respectively form the inter-gate dielectric layer 308a (308b), the charge storage layer 306a (306b) and the tunneling dielectric layer 304a (304b) at the same time when the conductive layer 310a (310b) is defined. Then, the mask is removed. The stack structure of the gate cap layer 312a (312b), the conductive layer 310a (310b) (control gate), the inter-gate dielectric layer 308a (308b), the charge storage layer 306a (306b) (floating gate) and the tunneling dielectric layer 304a (304b) form a stacked gate structure 314a (314b). Thereafter, a spacer 316 is formed on the side wall of the stack structure 314a (314b). The forming process of the spacer 316 includes, for example, first, forming an insulation layer (not shown), wherein the material of the insulation layer is, for example, silicon nitride; then, removing a part of the insulation layer in an anisotropic etching process.

Referring to FIG. 4D, a select gate dielectric 318 is formed in the substrate 300 between the stacked gate structure 314a and the stacked gate structure 314b. The material of the select gate dielectric layer 318 is, for example, silicon oxide, and the forming method of the select gate dielectric layer 318 is, for example, a thermal oxidation process. Then, a select gate 320 is formed in the gap between the stacked gate structure 314a and the stacked gate structure 314b. The forming method of the select gate 320 includes: for example, forming a conductive layer on the substrate in advance, then removing the conductive layer outside the gap.

Then, referring to FIG. 4E, using the select gate 320 and the stacked gate structure 314b as masks, a doping material implant process 322 is performed to implant the doping material in the substrate 300 outside of the stacked gate structure 314a and the stacked gate structure 314b to form the doped region 324 and the doped region 326. The method of implanting doping material in the substrate 300 includes an ion-implanting method.

Referring to FIG. 4F, an inner dielectric layer 336 is formed on the substrate 300. The material of the inner dielectric layer 336 is, for example, borophosphosilicate glass (BPSG) or phosphosilicate glass (PSG), and the forming method of the inner dielectric layer 336 is, for example, a chemical vapor deposition (CVD) process. Then, a chemical-mechanical grinding process is performed to flat the surface of the inner dielectric layer 336.

Next, the inner dielectric layer 336 is patterned to form an opening 325 by which the doped region 324 is exposed, and an opening 327 by which the doped region 326 is exposed. Next, conductive plugs 328, 330 are formed in the openings 325, 327 in the inner dielectric layer 336, respectively. The material of the conductive plugs 328, 330 is, for example, tungsten. The forming method of the conductive plugs 328, 330 is as follows. First, a conductive material layer is formed on the inner dielectric layer 336; then, the conductive material outside of the openings 325, 327 is removed. Thereafter, conductive wires 332, 334 are formed on the inner dielectric layer 336, wherein the conductive wires 332, 334 are electrically connected to the conductive plugs 328, 330, respectively. The forming method of the conductive wires 332, 334 includes, for example, performing a photolithography etching process after the conductive layer (not shown) is formed on the substrate 300.

In the embodiment, as the select gate dielectric layer 318 and select gate 320 are formed between the stacked gate structure 314a and the stacked gate structure 314b, another gate structure can be made between the stacked gate structure 314a and the stacked gate structure 314b without the photolithography etching process. Accordingly, the manufacturing process is relatively simple, and the cost can be reduced. Moreover, the non-volatile memory of the present invention adopts conductive wires as bit lines, but not the doped region (i.e., the so-called embedded bit line) as the bit line, so that the known disadvantages, such as the low programming efficiency and the low reading current resulting from the high resistance, can be avoided.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A non-volatile memory, comprising:
a substrate;
a memory unit array, comprising N memory unit columns, each memory unit column comprising M memory units (both N and M are positive integers), each memory unit comprising:
two doped regions, disposed in the substrate;
a first memory cell, a select gate structure, and a second memory cell, disposed between the two doped regions on the substrate, and the select gate structure sandwiched between the first memory cell and the second memory cell;
wherein among the memory units in a same column, the every adjacent memory units share a common doped region, and are connected in series;
(N+1) bit lines, disposed on the substrate and arranged in parallel in the column direction, wherein the (N+1) bit lines are corresponding to the N memory unit columns, each of the N memory unit columns is disposed between every two adjacent bit lines, and the doped regions of the memory unit column are connected to the corresponding two bit lines alternatively;
M word lines, disposed on the substrate, respectively, wherein the word lines are arranged in parallel in the row direction and respectively connected to the select gate structure in the same row;
M first control gate lines, arranged on the substrate in parallel in the row direction, wherein the M first gate lines are respectively connected to the first memory cell in the same row; and
M second control gate lines, arranged on the substrate in parallel in the row direction, wherein the M second control gate lines are respectively connected to the second memory cell in the same row.

2. The non-volatile memory as claimed in claim 1, wherein each of the first memory cells comprises:
a first gate;
a first composite layer, disposed under the first gate, wherein the first composite layer comprises a first bottom dielectric layer, a first charge storage layer and a first top dielectric layer; and
each of the second memory cells, comprises:
a second gate; and
a second composite layer, disposed under the second gate, wherein the second composite layer comprises a second bottom dielectric layer, a second charge storage layer and a second top dielectric layer.

3. The non-volatile memory as claimed in claim 2, wherein the material of the first charge storage layer and the second charge storage layer comprises silicon nitride.

4. The non-volatile memory as claimed in claim 2, wherein the material of the first bottom dielectric layer and the second bottom dielectric layer comprises silicon oxide.

5. The non-volatile memory as claimed in claim 2, wherein the material of the first charge storage layer and the second charge storage layer comprises doped polysilicon.

6. The non-volatile memory as claimed in claim 2, wherein the material of the first top dielectric layer and the second top dielectric layer comprises silicon oxide or oxide-nitride-oxide composite layer.

7. The non-volatile memory as claimed in claim 1, further comprising a pair of first insulation spacers, disposed on the sidewalls of the first memory cell; and
a pair of second insulation spacers, disposed on the sidewalls of the second memory cell.

8. The non-volatile memory as claimed in claim 7, wherein the material of the first insulation spacers and the second insulation spacers comprises silicon oxide or silicon nitride.

9. The non-volatile memory as claimed in claim 1, wherein the select gate structure further comprises:
a select gate; and
a select gate dielectric layer, disposed under the select gate.

10. The non-volatile memory as claimed in claim 1, further comprising a first control line and a second control line, arranged on the substrate in parallel in the column direction, and connected to the M first control gate lines and the M second control gate lines, respectively.

11. The non-volatile memory as claimed in claim 10, further comprising:
four gate lines, every two forming a group and disposed on the two sides of the memory unit array, respectively, wherein the gate lines are arranged in parallel in the row direction, crossing with the (N+1) bit lines; and
2(N+1) transistors, disposed at the two ends of the (N+1) bit lines, respectively;
wherein the bit lines are connected to gate lines via the transistors, respectively, and each one of four adjacent bit lines have their transistors connect to at least one different gate lines from the other bit lines.
